(19) United States
(12) Patent Application Publication
(10) Pub. No.: US 2024/0039335 A1
(43) Pub. Date: Feb. 1, 2024

(54) WIRELESS CHARGING DEVICE WITH USB-PD FUNCTION

(71) Applicant: Hitachi-LG Data Storage Korea, Inc., Seoul (KR)

(72) Inventors: Sucheol KIM, Seoul (KR); Cheol JIN, Seoul (KR); Chaemin JU, Seoul (KR); Yurak SON, Seoul (KR); Hyeongyeon CHO, Seoul (KR); Suyoung LEE, Seoul (KR); Hyunuk HA, Seoul (KR); Hogil LEE, Seoul (KR)

(73) Assignee: Hitachi-LG Data Storage Korea, Inc., Seoul (KR)

(21) Appl. No.: 18/227,397

(22) Filed: Jul. 28, 2023

(30) Foreign Application Priority Data
Jul. 29, 2022 (KR) 10-2022-0094467

(51) Int. Cl. H02J 50/10; H02J 50/70; H02J 50/00; H05K 7/20

(52) U.S. Cl. CPC H02J 50/10; H02J 50/70; H02J 50/005; H05K 7/20145

(57) ABSTRACT

The wireless charging device according to an embodiment may comprise a rectangular shield assembly in which a shield and a first coil for delivering power to a terminal including a second coil by magnetic induction coupling are formed, a main PCB including an inverter that converts DC power into AC power and supplies it to the first coil, and a sub-PCB attached to one corner of the shield assembly and including a USB Type-C port. The sub-PCB may be disposed outside the first coil. The USB Type-C port may be exposed in a direction perpendicular to a plane on which the terminal is placed.

### TECHNICAL FIELD

The present disclosure relates to a wireless charging device having a USB-PD function, and, more particularly, to a wireless charging device for a vehicle capable of charging using USB-PD in addition to wireless charging.

### BACKGROUND

Wireless charging refers to a technology in which power can be supplied from a device that sends power wirelessly to a device that receives power even when the two devices are not wired to each other. For example, the device receiving power may be a terminal such as a mobile phone, a smart phone, a PDA, or a tablet PC, and a battery provided inside the terminal may be charged by wireless charging.

In general, wireless charging technology is largely divided into a magnetic induction method, a magnetic resonance method, etc. The magnetic induction method is based on an electromagnetic induction phenomenon generated by the flow of electricity inside a device that sends power. For the magnetic resonance method to transfer power, when a certain resonance frequency is generated by the flow of electricity inside a device that sends power, a magnetic field is induced in a coil inside a device that receives power having a corresponding resonance frequency.

Most of newer models of vehicles are equipped with a wireless charging device for charging a smart phone. However, drivers of old models of vehicles not having a high-speed wireless charging device need to purchase a separate wireless charging device for a vehicle or a cigar jack as shown in FIG. 1A including a USB-Power Delivery (PD) port for high-speed charging of smart devices such as smart phones, smart pads, and laptop computers.

On the other hand, as shown in FIG. 1B, the latest models of automobiles are equipped with a USB-PD port for high-speed charging of a smart terminal as well as a wireless charging device and a general USB port (type-A port).

However, because a wireless charging device and a board for USB-PD are disposed in different areas of a vehicle, they are produced as separate parts and then assembled into the vehicle, which is not efficient in terms of cost or space usage.

### SUMMARY

In view of such a situation, the purpose of the present disclosure is to provide a wireless charging device for a vehicle having a USB-PD function.

Another purpose of the present disclosure is to provide a device and method for effectively controlling the amount of heat and a maximum output when wireless charging and charging by USB-PD are performed at the same time.

The wireless charging device according to an embodiment of this disclosure may comprise a rectangular shield assembly in which a shield and a first coil for delivering power to a terminal including a second coil by magnetic induction coupling are formed, a main PCB including an inverter that converts DC power into AC power and supplies it to the first coil, and a sub-PCB attached to one corner of the shield assembly and including a USB Type-C port.

The power controlling method in a wireless charging device according to another embodiment of this disclosure may comprise checking whether wirelessly charging a first terminal, checking whether a second terminal is connected to a USB-PD port, and setting a profile of USB-PD. The profile may be set low when the first terminal is being wirelessly charged and the second terminal is connected to the USB-PD port, and the profile may be set high when the first terminal is not in wireless charging and the second terminal is connected to the USB-PD port.

By integrating the wireless charging device and the USB-PD function, it may be possible to reduce the manufacturing costs and to efficiently use vehicle space.

In addition, when wireless charging and charging by the USB-PD are performed simultaneously, the maximum output of the device may be monitored in real time, and the power may be controlled by a single controller, so that it may be possible to control the output stably and efficiently.

### BRIEF DESCRIPTION OF THE DRAWINGS

FIG. 1A shows an example of charging a smart phone in a vehicle using a cigar jack including a USB-PD Type-C port.

FIG. 1B shows the interior of a vehicle including both a Tireless charging device and a USB Type-C port.

FIG. 2 is an exploded perspective view of a wireless charging device having a USB-PD function according to an embodiment of the present disclosure.

FIG. 3 shows the appearance of the wireless charging device with the interface surface for wireless charging and a USB Type-C port exposed on the top.

FIG. 4 shows a main PCB of the wireless charging device including a transmission coil and a sub-PCB for USB-PD placed at a corner.

FIG. 5 shows the sub-PCB including the USB Type-C port and an FFC connector.

FIG. 6 is a flowchart of a method of controlling power of the wireless charging device having the USB-PD function according to an embodiment of the present disclosure.

### DETAILED DESCRIPTION

Hereinafter, an embodiment of a wireless charging device having a USB-PD function will be described in detail based on the accompanying drawings.

Regardless of the reference numerals, the same or similar components are given the same reference numerals, and overlapping descriptions thereof will be omitted.

In describing the embodiments disclosed in this specification, when an element is referred to as being “connected” to another element, it may be directly connected to the other element, but it should be understood that other components may exist in the middle.

In addition, in describing the embodiments disclosed in this specification, if it is determined that a detailed description of a related known technology may obscure the gist of the embodiment disclosed in this specification, the detailed description will be omitted. In addition, the accompanying drawings are only for easy understanding of the embodiments disclosed in this specification, and the technical idea disclosed in this specification is not limited by the accompanying drawings. And it should be understood that all changes, equivalents or substitutes included in the spirit and technical scope of this specification is included. In addition, the numbers (eg, first, second, etc.) used in the description process of this specification are only identification symbols for distinguishing one component from another component.

“Module” and “unit”, which are suffixes for components used in the following description, are given or used together in consideration of ease of writing the specification, and do not have meanings or roles that are distinct from each other by themselves.

In addition, the term disclosure can be replaced with terms such as document, specification, and description.

For contact power delivery or wireless charging, while a receiving module including a matching circuit consisting of a receiving (Rx) coil (or a second coil) and a capacitor and a rectifying circuit is close to a transmitting module including a resonant circuit consisting of a transmitting (Tx) coil (or a first coil) and a capacitor, an inverter, etc., a high-frequency alternating current may be made flow through the first coil to generate magnetic coupling between the first coil and the second coil, thereby delivering power to the receiving module.

A switching element of the inverter that converts DC power into AC power and supplies high-frequency AC power to the first coil operates at a high frequency, generating a lot of heat in the inverter and the transmitting coil.

In order to allow a driver to easily charge a smart terminal such as a smart phone in his/her vehicle, recent vehicles generally include a wireless charging area with a built-in wireless charging device.

In addition, a USB Type-C port for the USB-PD function for high-speed charging of smart terminals such as smart phones, smart pads, and laptop computers is also being provided on dashboards or center fascias of vehicles.

For reference, USB-PD stands for USB power delivery, which is a protocol for supplying power to a device with a USB port through a USB cable. Because the USB-PD requires a communication pin (CC pin) for communicating with a terminal, a Type-C port and a cable are essential components of the USB-PD.

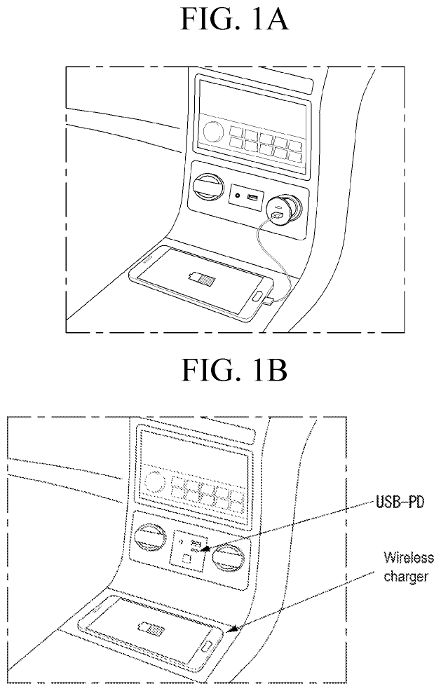

However, as shown in FIG. 1B, a wireless charging device and a USB port for the USB-PD function are disposed in different areas of a vehicle because wireless charging devices and USB-PD modules are manufactured as separate boards and integrated and assembled in vehicles.

According to an embodiment of the present disclosure, by integrating the USB-PD function into the wireless charging device and implementing both the wireless charging function and the USB-PD function at the same time, it may be possible to efficiently use vehicle space and cut down the manufacturing costs.

In addition, according to an embodiment of the present disclosure, there may be provided a method of controlling power of the device so that it may be possible to adjust an output stably while wireless charging and charging by the USB-PD are being performed at the same time.

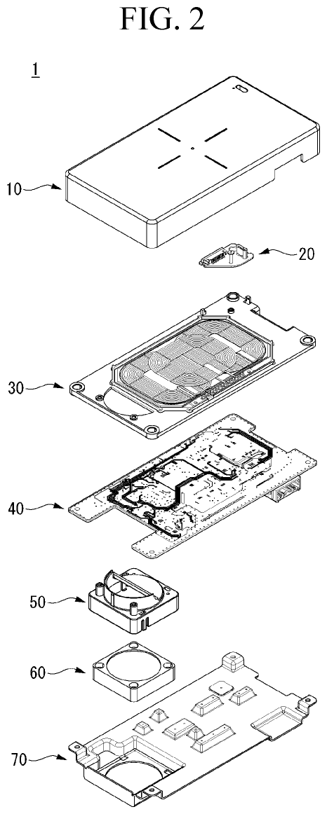

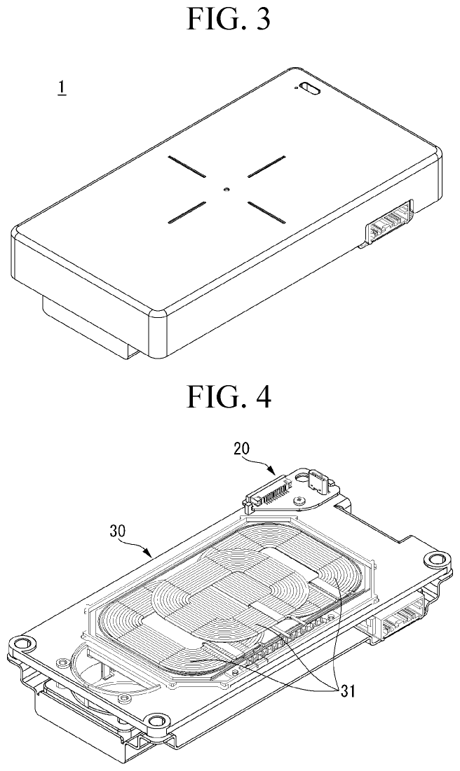

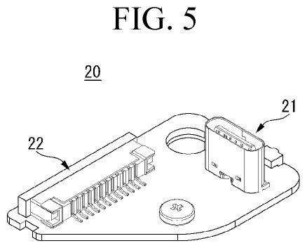

FIG. 2 is an exploded perspective view of a wireless charging device having the USB-PD function according to an embodiment of the present disclosure, FIG. 3 shows the appearance of the wireless charging device with the interface surface for wireless charging and a USB Type-C port exposed on the top, FIG. 4 shows a main PCB of the wireless charging device including a transmission coil and a sub-PCB for USB-PD placed at a corner, and FIG. 5 shows the sub-PCB including the USB Type-C port and an FFC connector.

A wireless charging device 1 having the USB-PD function according to an embodiment of the present disclosure may include an upper case 10 forming an upper surface on which a smart terminal including a receiving module is placed, a sub-PCB 20 for the USB-PD function, a shield assembly 30 in which a transmission coil is seated on a shield (e.g., a ferrite sheet; not shown) for blocking electromagnetic waves of the transmission coil, a main PCB 40 in which a power delivery module including an inverter, a processor, etc. are embedded, a fan holder 50, a fan motor 60 for generating air flow for cooling, and a lower case 70 that protects internal components together with the upper case 10 and forms the exterior of the device.

Because the change in a magnetic field generated in the transmission coil 31 through which a high-frequency alternating current flows may affect elements such as an inverter, a power supply device, a processor, a memory, etc. of a transmitting module, the transmission coil 31 of the wireless charging device 1 may be separated from other electronic elements by a shield sheet.

For convenience of assembly, the shield assembly including the transmission coil and the shield sheet and the main PCB 40 on which the inverter, the power supply device, the processor, the memory, etc. are mounted may be assembled in a module form. The shield assembly 30 may be disposed under the cover of the interface of the upper case 10 on which a smart terminal including a receiving module is placed, with the transmission coil 31 facing upward, and the main PCB 40 is placed below it.

A mark indicating a position where a smart terminal to be charged is placed may be displayed on the upper surface of the upper case 10. In addition, as shown in FIG. 3, the USB Type-C port may be exposed upward at a corner of the upper case 10 having a rectangular planar shape.

As shown in FIG. 4, the shield assembly 30 may include the transmission coil (Tx coil) 31 for wireless charging, and may further include a coil connector for connecting the transmission coil 31 to the main PCB 40.

The transmission coil 31 may consist of two or more coils for widening an active area corresponding to a position where a receiving module receives power, and may have a coil pattern formed in a multi-layered spiral path by the method of manufacturing a PCB. FIGS. 2 and 4 show the transmission coil 31 consisting of three coils.

The sub-PCB 20 may be disposed at a corner of the rectangular shield assembly 30, that is, on the outside of the transmission coil 31. In other words, the sub-PCB 20 may be placed away from the active area where the transmission coil 31 is placed, i.e., the position where a smart phone is placed, so that it may not affect the smart phone being wirelessly charged.

As shown in FIG. 5, the sub-PCB 20 may have the USB Type-C port facing upward, an FFC connector 22 for being connected to the main PCB 40, and an LED for displaying whether a USB is connected. The sub-PCB 20 may be disposed at a corner of the shield assembly 30 in a triangular or lozenge shape so that it may not affect the transmission coil 31.

In addition, the sub-PCB 20 may include or may not include a USB-PD module for performing the USB-PD function, as needed. The USB-PD module may be mounted on the main PCB 40, but, if so, it means that the main PCB 40 unnecessarily includes the USB-PD module even when the wireless charging device 1 does not need the USB-PD function. Furthermore, when the USB-PD module is removed from the sub-PCB 20, the sub-PCB 20 may simply serve to provide the USB Type-C port to the wireless charging device 1.

The sub-PCB 20 may be fixed to the shield assembly 30 by screws and guide hooks provided on the shield assembly 30.

Holes or grooves may be formed in the shield assembly 30 to form a path through which air flows by the pressure generated by the fan motor 60, and may be formed on opposite sides of each other so that the air passing path may cross the transmission coil 31.

As such, by modularizing the components of the wireless charging device 1, it may be possible to easily respond based on whether the wireless charging device 1 has to include the USB-PD function, reducing the manufacturing costs, and it may be possible to easily respond to customer requests, shortening the period for developing the device.

In addition, the USB Type-C port may be disposed on the upper surface of the wireless charging device for high-speed charging by USB-PD, so that it may be possible for a user to conveniently connect the second terminal to the USB while wirelessly charging another terminal.

In the meantime, when the USB-PD outputting a power of up to 60 W and the wireless charging device using a power of up to 15 W operate simultaneously, an input power of up to 75 W must be delivered to the device, and a high power of approximately 100 W must be input considering efficiency. In this case, due to the excessive input/output of power, heat may be generated, and a vehicle battery may be overloaded, so it may be necessary to control the output power of the device.

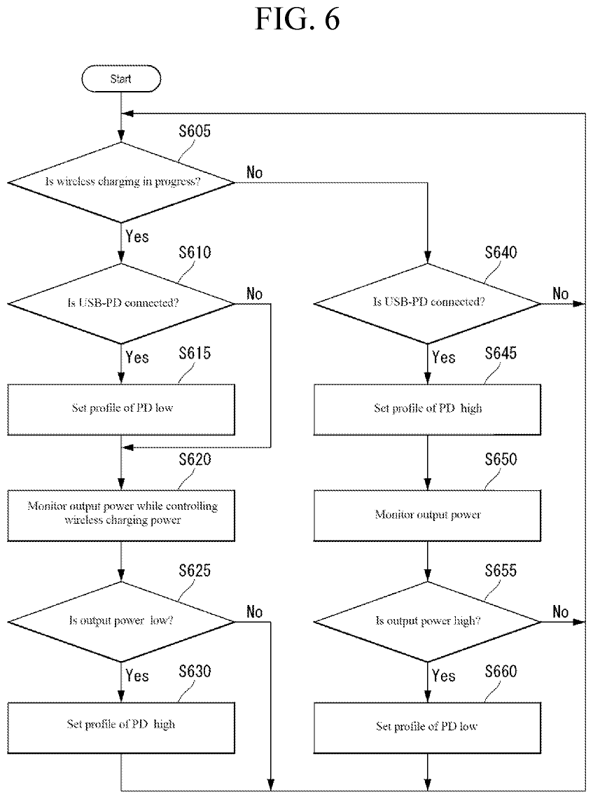

FIG. 6 is a flowchart of a method of controlling power of the wireless charging device having the USB-PD function according to an embodiment of the present disclosure.

The processor mounted on the main PCB 40 may check whether power is being wirelessly supplied to the first terminal placed on the upper case 10 by the transmitting module, that is, whether wireless charging is in progress at S605.

When wireless charging is in progress (Yes in S605), the processor may check whether a second terminal is connected to the USB Type-C port for the USB-PD function separately from the terminal in the wireless charging at S610.

When the second terminal is connected to the USB-PD (Yes in S610), the processor may set the profile of the USB-PD used to supply power to the second terminal low at S615 in order to reduce power consumed by the USB-PD considering that a lot of power may be consumed in the wireless charging.

The processor may monitor power delivered by the wireless charging and the USB-PD while controlling the power wirelessly supplied to the first terminal at S620.

The processor may compare the monitored output power with a predetermined value at S625, and may set the profile of the USB-PD high when the value of the output power is less than the predetermined value (Yes in S625) at S630, which means that the processor may increase the amount of power supplied by the USB-PD while determining that the wireless charging is not consuming much power. When the value of the output power is greater than the predetermined value (No in S625), the processor may maintain the profile of the USB-PD as it is.

On the other hand, when the wireless charging device is not in use (No in S605), the processor may check whether the second terminal is connected to the USB Type-C port for the USB-PD function at S640.

When the second terminal is connected to the USB-PD (Yes in S640), the processor may set the profile of the USB-PD used to supply power to the second terminal high at S645 in order to increase the amount of power supplied by the USB-PD considering that the wireless charging is not in progress.

The processor may monitor power delivered by the USB-PD at S650.

The processor may compare the value of the monitored output power with a predetermined value at S655 and may set the profile of the USB-PD low when the value of the output power is greater than the predetermined value (Yes in S655) at S660 in order to reduce the amount of power supplied by the USB-PD while determining that much power is being consumed by the USB-PD. When the value of the output power is less than the predetermined value (No in S655), the processor may maintain the profile of the USB-PD as it is.

As such, it may be possible to enable the device to operate efficiently and stably by solving the problem of power consumption that occurs when the wireless charging and the USB-PD are simultaneously performed to deliver power.

The wireless charging device according to the present disclosure can be described as follows.

The wireless charging device according to an embodiment of the present disclosure may include: a rectangular shield assembly in which a shield and a first coil for delivering power to a terminal including a second coil by magnetic induction coupling are formed; a main PCB including an inverter that converts DC power into AC power and supplies it to the first coil; and a sub-PCB attached to one corner of the shield assembly and including a USB Type-C port.

According to an embodiment of the present disclosure, the sub-PCB may be disposed outside the first coil.

According to an embodiment of the present disclosure, the USB Type-C port may be exposed in a direction perpendicular to the plane on which the terminal is placed.

According to an embodiment of the present disclosure, the sub-PCB may include a USB-PD module.

According to an embodiment of the present disclosure, the wireless charging device may further include a fan motor for generating air flow. Holes or grooves may be formed on opposite sides of the shield assembly so that an air passing path by pressure generated by the fan motor is formed across the first coil.

According to another embodiment of the present disclosure, the method of controlling power in the wireless charging device may involve checking whether wirelessly charging a first terminal; checking whether a second terminal is connected to a USB-PD port; and setting a profile of USB-PD. The profile may be set low when the first terminal is being wirelessly charged and the second terminal is connected to the USB-PD port, and the profile may be set high when the first terminal is not in wireless charging and the second terminal is connected to the USB-PD port.

According to another embodiment of the present disclosure, the method of controlling power of the wireless charging device may further involve monitoring output power. The profile may be set high when the monitoring shows that the output power is low in a state that the first terminal is being wirelessly charged and the second terminal is connected to the USB-PD port, and the profile may be set low when the monitoring shows that the output power is high in a state that the first terminal is not being wirelessly charged and the second terminal is connected to the USB-PD port.

What is claimed is:

1. A wireless charging device comprising:
a rectangular shield assembly in which a shield and a first coil for delivering power to a terminal including a second coil by magnetic induction coupling are formed;
a main PCB including an inverter that converts DC power into AC power and supplies it to the first coil; and
a sub-PCB attached to one corner of the shield assembly and including a USB Type-C port.

2. The wireless charging device of claim 1, wherein the sub-PCB is disposed outside the first coil.

3. The wireless charging device of claim 1, wherein the USB Type-C port is exposed in a direction perpendicular to a plane on which the terminal is placed.

4. The wireless charging device of claim 1, wherein the sub-PCB includes a USB-PD module.

5. The wireless charging device of claim 1, further comprising a fan motor for generating air flow, wherein holes or grooves are formed on opposite sides of the shield assembly so that an air passing path by pressure generated by the fan motor is formed across the first coil.

6. A method of controlling power in a wireless charging device, comprising:
checking whether wirelessly charging a first terminal;
checking whether a second terminal is connected to a USB-PD port; and
setting a profile of USB-PD,
wherein the profile is set low when the first terminal is being wirelessly charged and the second terminal is connected to the USB-PD port, and the profile is set high when the first terminal is not in wireless charging and the second terminal is connected to the USB-PD port.

7. The method of claim 6, further comprising monitoring output power,
wherein the profile is set high when the monitoring shows that the output power is low in a state that the first terminal is being wirelessly charged and the second terminal is connected to the USB-PD port, and the profile is set low when the monitoring shows that the output power is high in a state that the first terminal is not being wirelessly charged and the second terminal is connected to the USB-PD port.
